(19) United States
(12) Patent Application Publication
(10) Pub. No.: US 2025/0253446 A1
(43) Pub. Date: Aug. 7, 2025

(54) BATTERY COOLING SYSTEM FOR A BATTERY ELECTRIC VEHICLE

(71) Applicant: Scout Motors, Inc., Tysons, VA (US)

(72) Inventors: Eric Sandstrom, Tysons, VA (US); Sven-Oliver Muendemann, Tysons, VA (US)

(21) Appl. No.: 18/435,402

(22) Filed: Feb. 7, 2024

(51) Int. Cl. H01M 10/663; B60H 1/00; B60L 50/64; B60L 58/26; H01M 10/613; H01M 10/625; H01M 10/63; H01M 10/6556; H01M 10/6563; H01M 10/6568; H01M 50/213; H01M 50/249; H05K 7/20

(52) U.S. Cl. CPC H01M 10/663; B60H 1/00278; B60L 50/64; B60L 58/26; H01M 10/613; H01M 10/625; H01M 10/63; H01M 10/6556; H01M 10/6563; H01M 10/6568; H01M 50/213; H01M 50/249; H05K 7/20872; B60H 2001/003; H01M 2220/20

(57) ABSTRACT

A battery cooling system may include a battery housing configured to be coupled to a chassis of the battery electric vehicle. A battery cooling system may include a plurality of battery cells positioned within the battery housing, each of the plurality of battery cells including a pole. A battery cooling system may include a liquid cooling plate arranged in thermal communication with the poles of the plurality of battery cells. A battery cooling system may include a liquid cooling system providing coolant to the liquid cooling plate. A battery cooling system may include an airflow passageway defined between the battery housing and the plurality of battery cells. A battery cooling system may include a vehicle heating, ventilation, and air conditioning (HVAC) system providing cooled air to the airflow passageway.

### BACKGROUND

This disclosure relates to cooling systems for batteries. More specifically, the disclosure relates to battery cooling systems for electric vehicles.

Cooling systems for battery electric vehicles are used while driving and while charging to reduce aging of battery cells and to inhibit damage of the battery cells. More cooling performance is desirable for bigger vehicles, higher power, high charging performance, and high range.

### SUMMARY

In some aspects, the techniques described herein relate to a battery cooling system for a battery electric vehicle, the battery cooling system including: a battery housing configured to be coupled to a chassis of the battery electric vehicle; a plurality of battery cells positioned within the battery housing; a liquid cooling plate arranged in thermal communication with the plurality of battery cells; a liquid cooling system providing coolant to the liquid cooling plate; an airflow passageway defined between the battery housing and the plurality of battery cells; and a vehicle heating, ventilation, and air conditioning (HVAC) system providing cooled air to the airflow passageway.

In some aspects, the techniques described herein relate to a battery cooling system, wherein the battery housing includes an air inlet structured to receive the cooled air from the vehicle HVAC system and an air exhaust that vents to atmosphere.

In some aspects, the techniques described herein relate to a battery cooling system, wherein the liquid cooling plate is positioned within the battery housing.

In some aspects, the techniques described herein relate to a battery cooling system, wherein the liquid cooling plate is a top plate.

In some aspects, the techniques described herein relate to a battery cooling system, wherein each of the plurality of battery cells includes a pole, the battery cooling system further including a busbar connected between the poles of the plurality of battery cells, wherein the liquid cooling plate is arranged in thermal communication with the poles of the plurality of battery cells or the busbar.

In some aspects, the techniques described herein relate to a battery cooling system, wherein the airflow passageway includes gaps formed between the plurality of battery cells.

In some aspects, the techniques described herein relate to a battery cooling system, wherein the gaps are 1-3 mm.

In some aspects, the techniques described herein relate to a battery cooling system, wherein the plurality of battery cells are cylindrical battery cells.

In some aspects, the techniques described herein relate to a battery cooling system, wherein the vehicle HVAC system provides an active airflow through the airflow passageway.

In some aspects, the techniques described herein relate to a battery cooling system, further including a controller structured to control operation of the vehicle HVAC system and the liquid cooling system to maintain a battery cell temperature below a high temperature threshold.

In some aspects, the techniques described herein relate to a battery cooling system, further including a controller structured to control operation of the vehicle HVAC system and the liquid cooling system to maintain a battery cell temperature above a low temperature threshold.

In some aspects, the techniques described herein relate to a battery cooling system, further including a controller structured to control operation of the vehicle HVAC system and the liquid cooling system in a hybrid mode of operation with both the vehicle HVAC system and the liquid cooling system providing cooling to the plurality of battery cells simultaneously.

In some aspects, the techniques described herein relate to a battery cooling system, further including a controller structured to control operation of the vehicle HVAC system and the liquid cooling system simultaneously while the plurality of battery cells are being charged.

In some aspects, the techniques described herein relate to a battery cooling system, further including a controller structured to control operation of the vehicle HVAC system and the liquid cooling system simultaneously while an energy output of the plurality of battery cells is greater than an energy output threshold.

In some aspects, the techniques described herein relate to a battery cooling system, further including a controller structured to control operation of the vehicle HVAC system during charging of the plurality of battery cells and control operation of the liquid cooling system during driving.

In some aspects, the techniques described herein relate to a battery cooling system for a battery electric vehicle, the battery cooling system including: a battery system including a plurality of cylindrical battery cells; a single sided liquid cooling plate arranged in thermal communication with the battery system, the single sided liquid cooling plate configured to receive coolant; an airflow passageway formed within the battery system adjacent sides of the plurality of cylindrical battery cells; and a vehicle heating, ventilation, and air conditioning (HVAC) system providing cooled air to the airflow passageway.

In some aspects, the techniques described herein relate to a battery cooling system, further including: a liquid cooling system providing the coolant to the single sided liquid cooling plate; and a controller structured to: receive temperature information from the battery system, and operate the liquid cooling system and the vehicle HVAC system based on the temperature information.

In some aspects, the techniques described herein relate to a battery cooling system, wherein the controller is further structured to operate the liquid cooling system and the vehicle HVAC system simultaneously while charging the battery system.

In some aspects, the techniques described herein relate to a battery cooling system, wherein the controller is further structured to operate the liquid cooling system and the vehicle HVAC system to maintain the temperature information above a lower threshold temperature and below an upper threshold temperature.

In some aspects, the techniques described herein relate to a battery cooling system including: a top plate configured to receive coolant from a liquid cooling system and remove heat from poles and busbars of a battery system; and an airflow passageway configured to receive forced airflow from a vehicle heating, ventilation, and air conditioning system and remove heat from a side surface of the battery system.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF DRAWINGS

The device is explained in even greater detail in the following drawings. The drawings are merely exemplary and certain features may be used singularly or in combination with other features. The drawings are not necessarily drawn to scale.

FIG. 1 is a schematic representation of a battery electric vehicle including a battery cooling system, according to some implementations.

FIG. 2 is an exploded view of the battery cooling system of FIG. 1, according to some implementations.

FIG. 3 is a side view of the battery cooling system of FIG. 1, according to some implementations.

FIG. 4 is a top view of the battery cooling system of FIG. 1, according to some implementations.

FIG. 5 is a schematic representation of a battery cell of the battery electric vehicle of FIG. 1 cooled via liquid cooling only, according to some implementations.

FIG. 6 is a schematic representation of a battery cell of the battery electric vehicle of FIG. 1 cooled via liquid cooling and air cooling, according to some implementations.

FIG. 7 is a temperature legend for the schematic representations of FIGS. 5 and 6, according to some implementations.

FIG. 8 is a schematic diagram of a control system that operates the battery cooling system of FIG. 1, according to some implementations.

### DETAILED DESCRIPTION

Following below are more detailed descriptions of concepts related to, and implementations of, methods, apparatuses, and systems for cooling battery cells of a battery electric vehicle. Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

Referring to the figures generally, the various embodiments disclosed herein relate to systems, apparatuses, and methods for cooling battery cells of a battery electric vehicle. According to some implementations described herein, a battery cooling system includes a liquid cooling system in the form of a top plate positioned in thermal communication with busbars or poles of the battery cells. The top plate receives coolant from a heat exchanger and removes heat from the battery cells via the busbars or poles. The battery cooling system also includes an air cooling system in the form of air flow cavities that are provided between adjacent battery cells to provide air cooling of sides of the battery cells in conjunction with the liquid cooling provided by the top plate. A vehicle heating, ventilation, and air conditioning (HVAC) system provides forced air to the air flow cavities. In some implementations, the forced air provided by the vehicle HVAC system is cold air. The combined cooling from the air flow cavities (e.g., along the sides of the battery cells) and the top plate (i.e., liquid cooling) provides an increased level of cooling when compared to typical cooling systems that employ only top liquid cooling, or side liquid cooling, or passive air cooling. The systems described herein provide a low maintenance and cost solution to battery cooling during times of peak power draw (e.g., extended high grade uphill driving) or rapid charging.

As used herein the term “battery electric vehicle” means a vehicle (e.g., a passenger vehicle, a delivery vehicle, etc.) for use by humans or a self-driving vehicle that is powered entirely by a battery system including battery cells. In other words, no fossil fuels are utilized, no internal combustion engine is present in the vehicle, and no alternative forms of propulsion is provided (e.g., hydrogen fuel cells, etc.). In some implementations, features of this disclosure can be used with plug-in hybrid vehicles, hybrid vehicles (e.g., full hybrid vehicles), mild hybrid electric vehicles, and range extended hybrid vehicles.

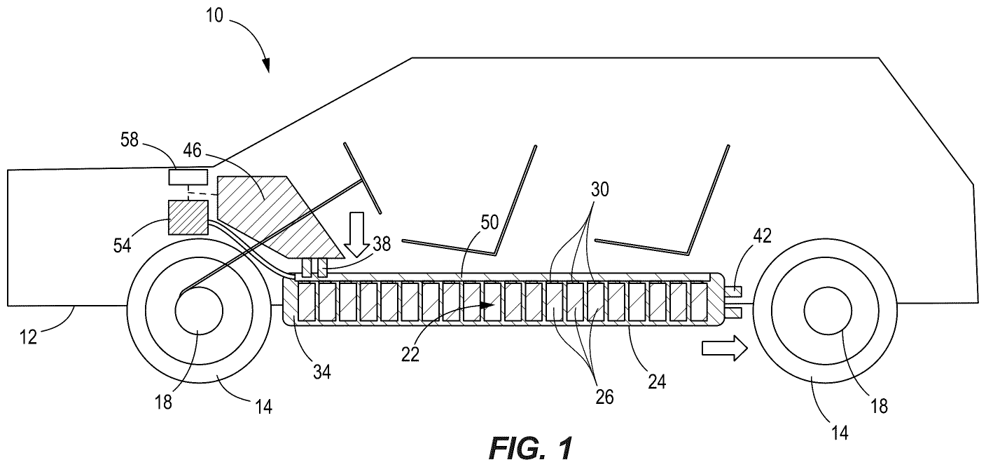

As shown in FIG. 1, a battery electric vehicle 10 includes a frame or chassis 12 (e.g., a truck frame, a unibody constructed chassis, etc.) and four wheels 14 driven by one or more battery powered electric machines 18.

A battery system 22 is supported within a battery housing 24 that is secured to the chassis 12. The battery system 22 includes battery cells 26 positioned within the battery housing 24. In some implementations, the battery cells 26 are cylindrical type cells. In some implementations, the battery cells 26 are prismatic or another battery cell geometry. Each of the battery cells 26 includes poles 30 (e.g., a positive pole and a negative pole) connected by busbars.

The battery cells 26 are spaced apart from one another by a gap to provide a cooling fluid passageway in the form of an airflow passageway 34 therebetween. In some implementations the airflow passageway 34 provides convective fluid cooling (e.g., via air, CO2, or another gaseous fluid) to remove heat from the battery cells 26. In some implementations, the battery cells 26 are spaced apart by a gap of 1-3 mm at their nearest points. In some implementations, the battery cells are spaced apart by a gap of more than 3 mm or less than 1 mm. In some implementations, the gaps or spaces between adjacent battery cells 26 are non-uniform or define a pattern of repeating spacings. The airflow passageway 34 is defined between an air inlet 38 and an air exhaust 42 of the battery housing 24. The airflow passageway 34 is shaped to provide air cooling along the sides of the battery cells 26. In other words, the airflow passageway 34 provides air cooling to sides of the battery cells 26 that are not collocated with the poles 30.

A vehicle heating, ventilation, and air conditioning (HVAC) system 46 is supported by the chassis 12 and provides conditioned air to a cabin of the vehicle 10 to support user comfort. The vehicle HVAC system 46 also selectively provides cooled air to the air inlet 38 so that a positive pressure or a forced airflow of cooled air is provided to the airflow passageway 34 for cooling the battery cells 26. Air that has absorbed heat from the battery cells 26 is exhausted to the atmosphere via the air exhaust 42. The combination of the vehicle HVAC system 46 and the airflow passageway 34 provides an air-cooling system for the battery cells 26. In some implementations, the HVAC system 46 includes an HVAC pump that moves a coolant or refrigerant through a refrigeration cycle and fans that move air across a heat exchanger. The cooled air that is moved by the fans is then provided to the airflow passageway 34 and/or to the cabin of the vehicle 10. In some implementations, the HVAC system 46 also include gate valves or other types of valves that selectively direct airflow to the cabin (e.g., selective areas of the cabin) and/or to the airflow passageway 34. As used herein, “HVAC” includes a traditional compressed refrigerant system, cryogenic cooling systems, Peltier cooling systems, and/or other cooling systems.

The battery system 22 also includes a liquid cooling plate in the form of a top plate 50 mounted to the poles 30 of each of the battery cells 26 and/or the busbars connecting the poles 30 together. The top plate 50 receives cold coolant from a liquid cooling system 54 (e.g., a pump or compressor, a heat exchanger, an expansion valve, etc.) and removes heat from the poles 30 and/or the busbars. In some implementations, the liquid cooling system 54 includes a liquid cooling pump that moves coolant, refrigerant, or another liquid through a heat exchange system (e.g., a refrigerant system either separate from or integrated with the HVAC system 46) and provides cooled liquid to the top plate 50. The top plate 50 is generally planar and contacts only a single side of the battery cells 26 as opposed to side cooling plates that provide heat exchange with the sides or multiple faces of the battery cells 26. In some implementations, the liquid cooling plate is a bottom plate arranged on a bottom side of the battery cells 26. In some implementations, the liquid cooling plate is not collocated with the poles 30.

A controller 58 is arranged in communication with the vehicle HVAC system 46 and the liquid cooling system 54 to control operation thereof and provide 1) a liquid cooling only mode, 2) hybrid cooling mode including both or combined liquid and air cooling, 3) air only cooling, or 4) no cooling to the battery system 22. The controller 58 receives battery temperature information (e.g., temperature of each battery cell 26, an average temperature of the battery cells 26, a single or multi-point temperature within the battery housing 24, etc.), vehicle operational information (e.g., driving mode, power usage of the one or more battery powered electric machines 18, look-ahead information or forecasted power usage information, etc.), and charging information (e.g., actively charging, projected time to full battery, charging mode such as bulk charging, etc.). Based on the received information, the controller 58 controls operation of the liquid cooling system 54 and the vehicle HVAC system 46 to provide cooling to the battery cells 26 to maintain a temperature of the battery system 22 equal to or less than an upper temperature threshold. In a heating mode of operation, the controller 58 can operate the liquid cooling system 54 and the vehicle HVAC system 46 to provide heat to the battery system 22 to maintain a temperature of the battery system 22 equal to or greater than a lower temperature threshold. The ability of the controller 58 to control the air-cooling system and the liquid cooling system alone or in combination provides four operation modes and an improved ability to meet cooling needs efficiently during many vehicle use cases when compared to typical cooling systems that employ only air cooling or only liquid cooling. The air-cooling system and the liquid cooling system are both redundant and synergistic because they provide cooling to the same battery cells 26 and improve the ability of the other system to effectively cool the battery cells 26.

In operation, the controller 58 operates the liquid cooling system 54 and cools the poles 30 and/or busbars using the top plate 50 while the vehicle 10 is turned on (e.g., driving or otherwise in use) and while the battery system 22 is being charged. In some implementations, the liquid cooling system 54 provides variable cooling. For example, when less cooling is required, a low power mode (e.g., running a compressor at lower pressure or a slower speed) may be utilized. The liquid cooling system 54 can be operated independent of the air cooling system and the vehicle HVAC system 46. For example, a liquid cooling only mode of operation may be used while driving or during periods of low energy charging.

The controller 58 also operates the vehicle HVAC system 46 to provides a flow of cooled air through the airflow passageways 34 between the air inlet 38 and the air exhaust 42 to cool the sides of the battery cells 26 not in contact with the top plate 50. The vehicle HVAC system 46 can be operated independently of the liquid cooling system 54. For example, the vehicle HVAC system 46 can be operated in cooperation with the liquid cooling system 54 during high energy charging or when the driving information indicates that an energy output of the battery system 22 exceeds a high energy threshold (e.g., a prolonged period of uphill driving at a high speed).

The vehicle HVAC system 46 and the liquid cooling system 54 provide a hybrid cooling system including a single-sided liquid cooling and air cooling. In some implementations, the liquid cooling system 54 provides the primary cooling of the poles 30 and/or the busbars of each battery cell 26 to maintain the temperature of the battery cells 26 below the high temperature threshold during charging and discharging and to maintain a continuity and resistance of the electrical connections at the poles 30 and busbars above an efficiency threshold. Therefore, the cooling of the poles 30 and/or busbars provides advantages beyond simply maintaining a desirable temperature within the battery cells 26. The combination of the top plate 50 and the use of the vehicle HVAC system 46 also provides adequate cooling while reducing weight, cost, and complexity when compared to a vertical or two-sided liquid cooling system. The hybrid cooling system including both the liquid cooling system 54 and the air-cooling system including the vehicle HVAC system 46 provides redundant systems (i.e., both an air cooling and a liquid cooling systems). Typical battery cooling systems employ only air cooling or only liquid cooling with the purpose of reducing cost and/or complexity. The hybrid cooling system has been found to provide improved cooling results and improved cooling efficiency compared to typical systems.

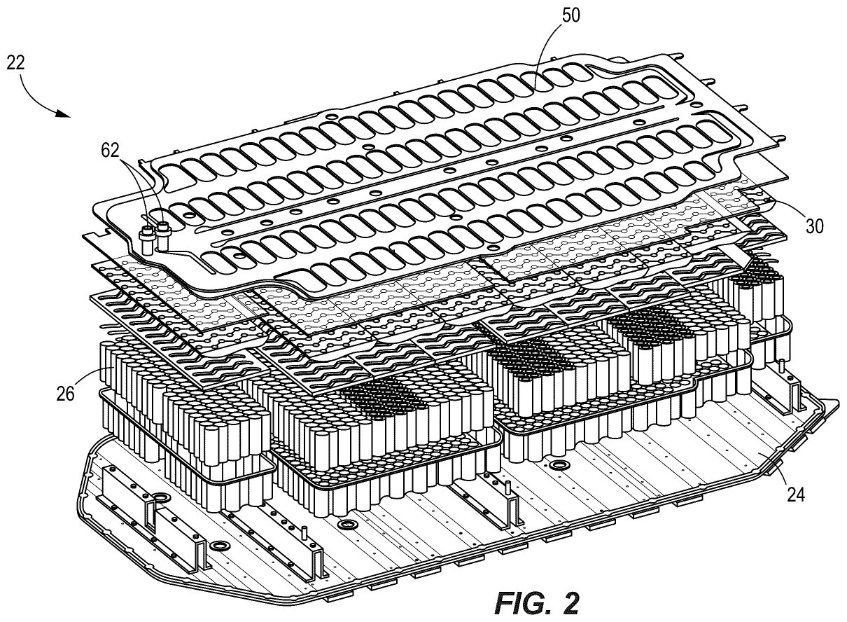

As shown in FIG. 2, the battery system 22 can be built to provide a heat exchange relationship between the top plate 50 and the battery cells 26. In some implementations, the top plate 50 includes a coolant inlet/outlet 62 connected to the liquid cooling system 54 (e.g., by piping).

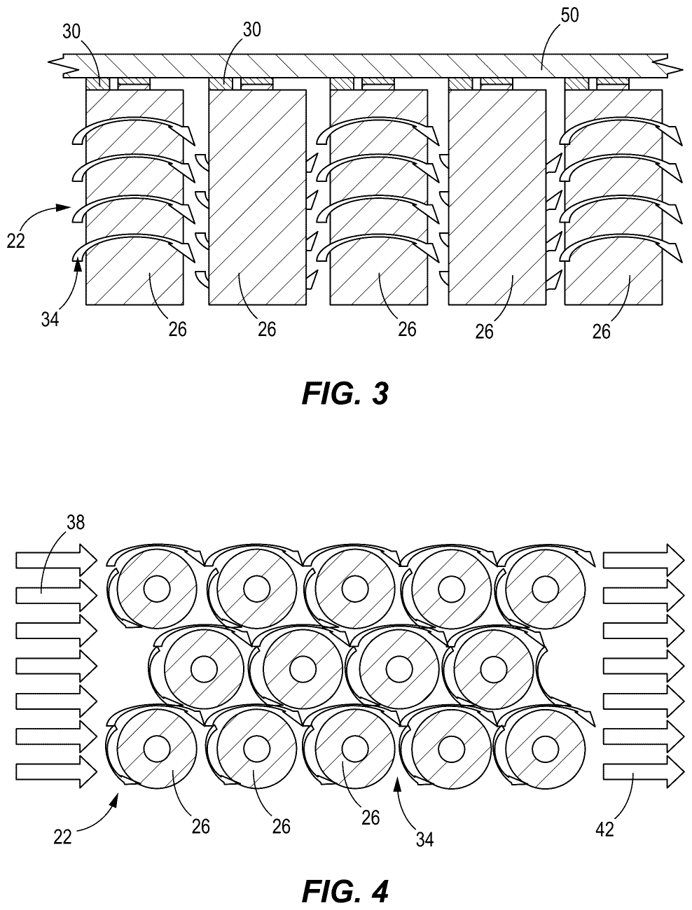

As shown in FIGS. 3 and 4, the spaces formed between adjacent battery cells 26 provide the airflow passageway 34 between the air inlet 38 and the air exhaust 42 to allow for the airflow to cool the sides of the battery cells 26. In some implementations, the battery cells 26 are arranged in a nested pattern to decrease the space claim of the battery system 22 while maximizing available power while providing the airflow passageway 34.

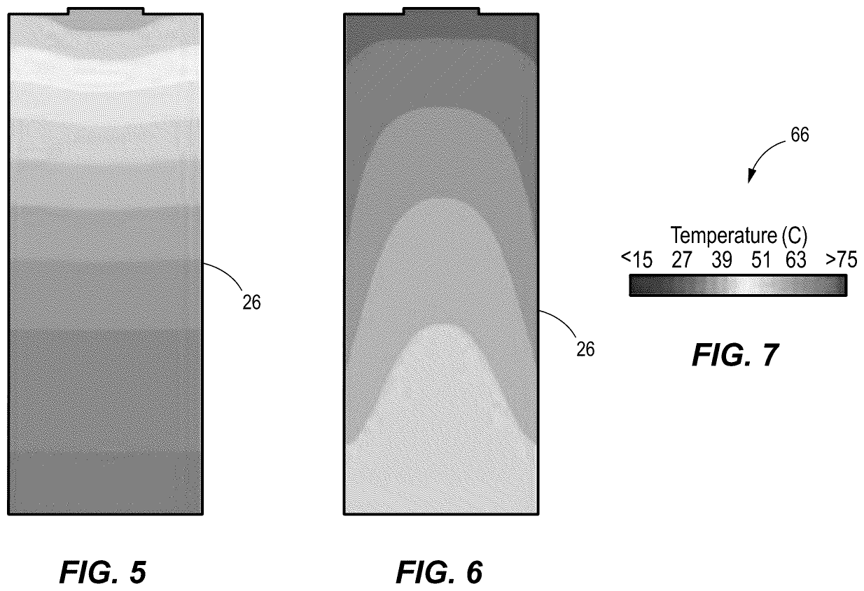

As shown in FIGS. 5-7, the hybrid cooling system including liquid cooling and active air cooling provides improved cooling when compared to cooling systems that employ a single sided liquid cooling only. FIG. 5 shows a simulation of a battery cell 26 operated during a period of high demand with only the top plate 50 and liquid cooling system 54 providing cooling. FIG. 6 shows a simulation with the same demand as the simulation of FIG. 5, but also includes the active air cooling provided by the vehicle HVAC system 46 and the airflow passageway 34. FIG. 7 includes a legend of a temperature gradient 66 used to illustrate temperature distribution in FIGS. 5 and 6.

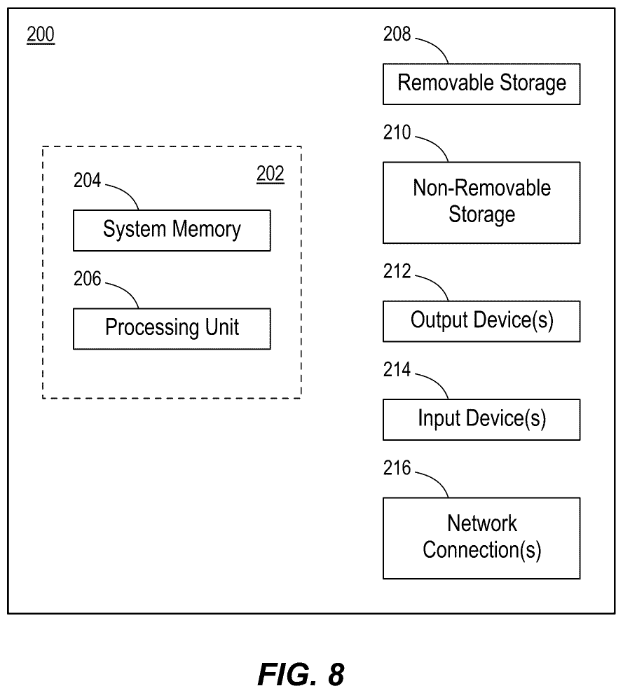

It should be appreciated that the logical operations described herein with respect to the controller 58 and/or various figures may be implemented (1) as a sequence of computer implemented acts or program modules (i.e., software) running on a computing device (e.g., the computing device described in FIG. 8), (2) as interconnected machine logic circuits or circuit modules (i.e., hardware) within the computing device and/or (3) a combination of software and hardware of the computing device. Thus, the logical operations discussed herein are not limited to any specific combination of hardware and software. The implementation is a matter of choice dependent on the performance and other requirements of the computing device. Accordingly, the logical operations described herein are referred to variously as operations, structural devices, acts, or modules. These operations, structural devices, acts, and modules may be implemented in software, in firmware, in special purpose digital logic, and any combination thereof. It should also be appreciated that more or fewer operations may be performed than shown in the figures and described herein. These operations may also be performed in a different order than those described herein.

Referring to FIG. 8, an example computing device 200 upon which the methods described herein may be implemented is illustrated. It should be understood that the example computing device 200 is only one example of a suitable computing environment upon which the methods described herein may be implemented. Optionally, the computing device 200 can be a well-known computing system including, but not limited to, personal computers, servers, handheld or laptop devices, multiprocessor systems, microprocessor-based systems, network personal computers (PCs), minicomputers, mainframe computers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 200 typically includes at least one processing unit 206 and system memory 204. Depending on the exact configuration and type of computing device, system memory 204 may be volatile (such as random access memory (RAM)), non-volatile (such as read-only memory (ROM), flash memory, etc.), or some combination of the two. This most basic configuration is illustrated in FIG. 8 by box 202. The processing unit 206 may be a standard programmable processor that performs arithmetic and logic operations necessary for operation of the computing device 200. The computing device 200 may also include a bus or other communication mechanism for communicating information among various components of the computing device 200.

Computing device 200 may have additional features/functionality. For example, computing device 200 may include additional storage such as removable storage 208 and non-removable storage 210 including, but not limited to, magnetic or optical disks or tapes. Computing device 200 may also contain network connection(s) 216 that allow the device to communicate with other devices. Computing device 200 may also have input device(s) 214 such as a keyboard, mouse, touch screen, etc. Output device(s) 212 such as a display, speakers, printer, etc. may also be included. The additional devices may be connected to the bus in order to facilitate communication of data among the components of the computing device 200. All these devices are well known in the art and need not be discussed at length here.

The processing unit 206 may be configured to execute program code encoded in tangible, computer-readable media. Tangible, computer-readable media refers to any media that is capable of providing data that causes the computing device 200 (i.e., a machine) to operate in a particular fashion. Various computer-readable media may be utilized to provide instructions to the processing unit 206 for execution. Example tangible, computer-readable media may include, but is not limited to, volatile media, non-volatile media, removable media and non-removable media implemented in any method or technology for storage of information such as computer readable instructions, data structures, program modules or other data. System memory 204, removable storage 208, and non-removable storage 210 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 206 may execute program code stored in the system memory 204. For example, the bus may carry data to the system memory 204, from which the processing unit 206 receives and executes instructions. The data received by the system memory 204 may optionally be stored on the removable storage 208 or the non-removable storage 210 before or after execution by the processing unit 206.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high level procedural or object-oriented programming language to communicate with a computer system. However, the program(s) can be implemented in assembly or machine language, if desired. In any case, the language may be a compiled or interpreted language and it may be combined with hardware implementations.

For purposes of this description, certain advantages and novel features of the aspects and configurations of this disclosure are described herein. The described methods, systems, and apparatus should not be construed as limiting in any way. Instead, the present disclosure is directed toward all novel and nonobvious features and aspects of the various disclosed aspects, alone and in various combinations and sub-combinations with one another. The disclosed methods, systems, and apparatus are not limited to any specific aspect, feature, or combination thereof, nor do the disclosed methods, systems, and apparatus require that any one or more specific advantages be present or problems be solved.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

Features disclosed in this specification (including any accompanying claims, abstract, and drawings), and/or all of the steps of any method or process so disclosed, may be combined in any combination, except combinations where at least some of such features and/or steps are mutually exclusive. The claimed features extend to any novel one, or any novel combination, of the features disclosed in this specification (including any accompanying claims, abstract, and drawings), or to any novel one, or any novel combination, of the steps of any method or process so disclosed.

As used in the specification and the appended claims, the singular forms “a”, “an”, and “the” include plural referents unless the context clearly dictates otherwise. Ranges may be expressed herein as from “about” one particular value, and/or to “about” another particular value. When such a range is expressed, another aspect includes from the one particular value and/or to the other particular value. Similarly, when values are expressed as approximations, by use of the antecedent “about”, it will be understood that the particular value forms another aspect. It will be further understood that the endpoints of each of the ranges are significant both in relation to the other endpoint, and independently of the other endpoint. The terms “about” and “approximately” are defined as being “close to” as understood by one of ordinary skill in the art. In one non-limiting aspect the terms are defined to be within 10%. In another non-limiting aspect, the terms are defined to be within 5%. In still another non-limiting aspect, the terms are defined to be within 1%.

The terms “coupled”, “connected”, and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

Certain terminology is used in the following description for convenience only and is not limiting. The words “right”, “left”, “lower”, and “upper” designate direction in the drawings to which reference is made. The words “inner” and “outer” refer to directions toward and away from, respectively, the geometric center of the described feature or device. The words “distal” and “proximal” refer to directions taken in context of the item described and, with regard to the instruments herein described, are typically based on the perspective of the practitioner using such instrument, with “proximal” indicating a position closer to the practitioner and “distal” indicating a position further from the practitioner. The terminology includes the above-listed words, derivatives thereof, and words of similar import.

Throughout the description and claims of this specification, the word “comprise” and variations of the word, such as “comprising” and “comprises”, means “including but not limited to”, and is not intended to exclude, for example, other additives, components, integers or steps. “Exemplary” means “an example of” and is not intended to convey an indication of a preferred or ideal aspect. “Such as” is not used in a restrictive sense, but for explanatory purposes.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention.

What is claimed is:

1. A battery cooling system for a battery electric vehicle, the battery cooling system comprising:
a battery housing configured to be coupled to a chassis of the battery electric vehicle;
a plurality of battery cells positioned within the battery housing;
a liquid cooling plate arranged in thermal communication with the plurality of battery cells;
a liquid cooling system providing coolant to the liquid cooling plate;
an airflow passageway defined within the battery housing and between the plurality of battery cells; and
a vehicle heating, ventilation, and air conditioning (HVAC) system providing cooled air to the airflow passageway.

2. The battery cooling system of claim 1, wherein the battery housing includes an air inlet structured to receive the cooled air from the vehicle HVAC system and an air exhaust that vents to atmosphere.

3. The battery cooling system of claim 1, wherein the liquid cooling plate is positioned within the battery housing.

4. The battery cooling system of claim 1, wherein the liquid cooling plate is a top plate.

5. The battery cooling system of claim 1, wherein each of the plurality of battery cells includes a pole,
further comprising a busbar connected between the poles of the plurality of battery cells,
wherein the liquid cooling plate is arranged in thermal communication with the poles of the plurality of battery cells or the busbar.

6. The battery cooling system of claim 1, wherein the airflow passageway includes gaps formed between the plurality of battery cells.

7. The battery cooling system of claim 6, wherein the gaps are 1-3 mm.

8. The battery cooling system of claim 1, wherein the plurality of battery cells are cylindrical battery cells.

9. The battery cooling system of claim 1, wherein the vehicle HVAC system provides an active airflow through the airflow passageway.

10. The battery cooling system of claim 1, further comprising a controller structured to control operation of a HVAC pump and HVAC fan of the vehicle HVAC system and a liquid pump of the liquid cooling system to maintain a battery cell temperature below a high temperature threshold.

11. The battery cooling system of claim 1, further comprising a controller structured to control operation of the vehicle HVAC system and the liquid cooling system to maintain a battery cell temperature above a low temperature threshold.

12. The battery cooling system of claim 1, further comprising a controller structured to control operation of the vehicle HVAC system and the liquid cooling system in a hybrid mode of operation with both the vehicle HVAC system and the liquid cooling system providing cooling to the plurality of battery cells simultaneously.

13. The battery cooling system of claim 1, further comprising a controller structured to control operation of the vehicle HVAC system and the liquid cooling system simultaneously while the plurality of battery cells are being charged.

14. The battery cooling system of claim 1, further comprising a controller structured to control operation of the vehicle HVAC system and the liquid cooling system simultaneously while an energy output of the plurality of battery cells is greater than an energy output threshold.

15. The battery cooling system of claim 1, further comprising a controller structured to control operation of the vehicle HVAC system during charging of the plurality of battery cells and control operation of the liquid cooling system during driving.

16. A battery cooling system for a battery electric vehicle, the battery cooling system comprising:
a battery system including a plurality of cylindrical battery cells;
a single sided liquid cooling plate arranged in thermal communication with the battery system, the single sided liquid cooling plate configured to receive coolant;
an airflow passageway formed within the battery system adjacent sides of the plurality of cylindrical battery cells; and
a vehicle heating, ventilation, and air conditioning (HVAC) system providing cooled air to the airflow passageway.

17. The battery cooling system of claim 16, further comprising:
a liquid cooling system providing the coolant to the single sided liquid cooling plate; and
a controller structured to:
receive temperature information from the battery system, and
operate the liquid cooling system and the vehicle HVAC system based on the temperature information.

18. The battery cooling system of claim 17, wherein the controller is further structured to operate the liquid cooling system and the vehicle HVAC system simultaneously while charging the battery system.

19. The battery cooling system of claim 17, wherein the controller is further structured to operate the liquid cooling system and the vehicle HVAC system to maintain the temperature information above a lower threshold temperature and below an upper threshold temperature.

20. A battery cooling system comprising:
a top plate configured to receive coolant from a liquid cooling system and remove heat from poles and busbars of a battery system; and
an airflow passageway configured to receive forced airflow from a vehicle heating, ventilation, and air conditioning system and remove heat from a side surface of the battery system.
